(19) United States
(12) Patent Application Publication
(10) Pub. No.: US 2016/0330546 A1
(43) Pub. Date: Nov. 10, 2016

(54) HEADSET WITH LEAKAGE DETECTION

(71) Applicants: Derek Boyd Barrentine, Gilroy, CA (US); Anand A. Parthasarath, Cupertino, CA (US)

(72) Inventors: Derek Boyd Barrentine, Gilroy, CA (US); Anand A. Parthasarath, Cupertino, CA (US)

(73) Assignee: AliphCom, San Francisco, CA (US)

(21) Appl. No.: 14/705,888

(22) Filed: May 6, 2015

(51) Int. Cl. H04R 3/04; H04M 1/725; G10K 11/178; H03G 5/16; H04R 1/10

(52) U.S. Cl. CPC H04R 3/04; H03G 5/165; H04R 1/1041; G10K 11/178; H04M 1/72527; H04R 2460/01; H04R 2201/103; H04R 2420/07

(57) ABSTRACT

A headset (e.g., on-ear headphone, over-ear headphone, earphones, earbuds, in-ear headphone, etc.) may include one or more transducers (e.g., microphones, accelerometers, vibration sensors, etc.) operative to measure leakage of sound generated by a loudspeaker(s) of the headset (e.g., leakage from an imperfect seal between a headset interface and a pinna interface). The headset may receive content from a memory, a wireless communications link (e.g., Bluetooth, WiFi, NFC) and/or from a wired communications link (e.g., a headphone cable or a USB cable). The headset may include systems to detect the leakage and adjust audio parameters (e.g., frequency response, equalization, etc.) caused by the leakage. Active noise cancellation and/or active leakage path(s) may be used to adjust the audio parameters.

### FIELD

Embodiments of the present application relate generally to electrical and electronic hardware, computer software, wired and wireless communications, Bluetooth systems, RF systems, low power RF systems, near field RF systems, portable personal wireless devices, signal processing, audio transducers, headsets, and consumer electronic (CE) devices.

### BACKGROUND

Headsets (also referred to as headphones), such as over-ear headphones, on-ear headphones, in-ear headphones, headsets with custom made ear molds and other types of headsets, designed either for mono listening (e.g., in a single ear) or for duo listening (e.g., in both ears), may come in different configurations, with typical configurations including an open-back design and a closed-back design (also referred to a sealed or sealed-back design). Less prevalent are semi-open headsets which provide a compromise between open-back and closed-back designs. Each type of headset may have advantages and disadvantages relative to other types of headsets; however, each headset design will typically include a mechanical structure operative as an interface between a sound delivery system (e.g., a loudspeaker and ear buds or ear pads, etc.) and a head and/or ear(s) of a user who dons the headset. After a headset is donned, the interface is positioned in contact with portions of the user's head and/or ears (e.g., inserted into a canal of the ear, etc.). The type of interface will typically determine a form the contact takes, such as ear pads or ear muffs for on-ear or over-ear headphones in which a headband, neckband or other structure that connects each ear cup (e.g., right and left ear cups) with each other and also facilitates mounting of the headphones to the head and positioning of the ear pads relative to each ear. Similarly, ear tips, ear buds, ear molds, or other type of interface structures configure to couple and/or mount the headphones to the head or ear, may be positioned in the ear or inserted into a canal of the ear. After being donned by the user, the interface structures (e.g., ear pad or ear bud) may form an imperfect acoustic seal with the head and/or ears of the user. Air gaps between the interface structures and the head and/or ears of the user may provide one type of leakage path for sound being generated from the loudspeakers in one or both interface structures to escape. If the sound being produced by the loudspeakers is of sufficient volume, the sound leakage may be heard by other persons in proximity of the user (e.g., sitting next to the user on an airplane).

Leakage from a headset may also affect audio quality as perceived by the user. Frequency response is one area that may be affected by leakage. For example, loss of low frequencies (e.g., below 200 Hz) may occur due to leakage. Low frequency losses may manifest as a reduced amplitude (e.g., in dB's) as a function of frequency in a low frequency region of the headsets overall frequency response. Ideally, the overall frequency response amplitude would be linear (e.g., flat) from the lowest frequencies the headset can produce to the highest frequencies the headset can produce. However, what typically occurs is a fall off of amplitude vs. frequency at the lower frequency regime.

Accordingly, there is a need for systems, apparatus and methods for remediating effects of sound leakage on audio performance of headsets.

### BRIEF DESCRIPTION OF THE DRAWINGS

Various embodiments or examples (“examples”) are disclosed in the following detailed description and the accompanying drawings:

FIG. 1 depicts one example of a flow for a headset with leakage detection;

FIG. 2 depicts examples of conventional ear pads, earbuds, eartips, and ear molds used for a variety of conventional headsets;

FIG. 3 depicts an example of a headset with leakage detection;

FIG. 4 depicts one example of a block diagram for a headset with leakage detection;

FIG. 5 depicts examples of a cross-sectional view of a headset with leakage detection and of a block-diagram of hardware and/or software that may be used to implement leakage detection and correction;

FIG. 6 depicts various examples of frequency response profiles and audio signals for a headset with leakage detection;

FIG. 7 depicts an example of frequency response profiles for a first and a second channel of a headset with leakage detection;

FIG. 8 depicts examples of a cross-sectional view of a headset with leakage detection and automatic noise cancellation and of a block-diagram of hardware and/or software that may be used to implement leakage detection, leakage correction and automatic noise cancellation;

FIG. 9 depicts examples of transducer waveforms and generated waveforms for a headset including leakage detection and automatic noise cancellation.

FIG. 10 depicts examples of a headset with leakage detection that includes active leakage paths; and

FIG. 11 depicts examples of circuitry and a frequency response profile for a headset with leakage detection that includes active leakage paths.

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples may be implemented in numerous ways, including as a system, a process, a method, an apparatus, a user interface, or a series of executable program instructions included on a non-transitory computer readable medium. Such as a non-transitory computer readable medium or a computer network where the program instructions are sent over optical, electronic, or wireless communication links and stored or otherwise fixed in a non-transitory computer readable medium. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For clarity, technical material that is known in the technical fields related to the examples has not been described in detail to avoid unnecessarily obscuring the description.

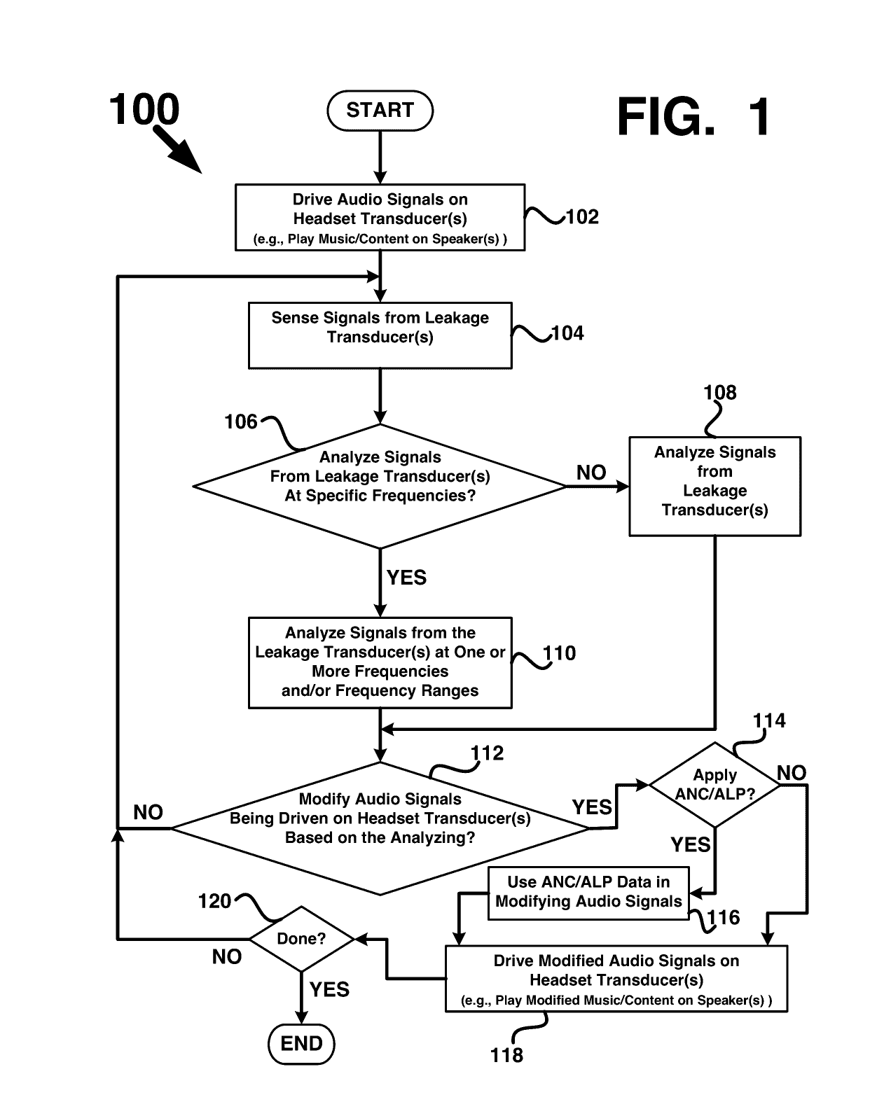

Attention is now directed to FIG. 1 where one example of a flow 100 for a headset with leakage detection is depicted. Flow 100 may be implemented using circuitry and/or one or more non-transitory computer readable mediums including program instructions and/or data operative to execute on one or more compute engines (e.g., a processor, controller, μP, μC, DSP, FPGA, ASIC, etc.). Examples of non-transitory computer readable mediums includes but is not limited to electronic memory, RAM, DRAM, ROM, EEPROM, Flash memory, and non-volatile memory, for example.

At a stage 102 audio signals (e.g., presentation of music, speech, or other content) may be coupled (e.g., applied by an audio amplifier) on a transducer or transducers in the headset. A headset may include a single sound generating transducer (e.g., a loudspeaker that covers a wide range of frequencies) or may include a number of sound generating transducers (e.g., one loudspeaker for low to middle frequencies and another loudspeaker for high frequencies, such as a tweeter). Each sound generating transducer may include terminals or nodes (e.g., speaker terminals) that may be coupled with amplifier circuitry configured to apply an audio signal to the terminals to generate sound. Multiple amplifiers may drive audio signals on a number of sound generating transducers (loudspeaker(s) hereinafter) in the headset (e.g., bi-amplification, tri-amplification, etc.). Audio signals may be received by the headset via a hardwired cable (e.g., a headphone cable), a memory (e.g., Flash memory) internal to the headphone that stores audio data, a memory external to the headphone that stores audio data, a communications link (e.g., a wireless link) with an external device (e.g., a smartphone) or external system (e.g., a wireless access point), just to name a few.

At a stage 104 signals from one or more leakage transducers (e.g., microphones, accelerometers, MEMS devices, piezoelectric devices, etc.) are sensed. Sensing may include analog and/or digital circuitry reading or otherwise processing the signals from the one or more leakage transducers that are coupled with the circuitry.

At a stage 106 a decision may be made as to whether or not to analyze the signals that were sensed at the stage 104 at one or more specific frequencies. For example, sound leakage from the sound produced by driving the audio signals on the transducer(s) at the stage 102 may affect frequency response of the headset at one or more specific frequencies, one or more specific frequency ranges, or over a wide range of frequencies. As one example, a low frequency response of the headset may be affected by the sound leakage, and the stage 106 may analyze one or more low frequency points (e.g., 80 Hz, 110 Hz, and 150 Hz) or one or more low frequency ranges (e.g., 70-100 Hz, 100-160 Hz). As another example, the stage 106 may analyze signals over a wider frequency range, such as a full frequency range of the headset of 65 Hz-20 KHz, or a subset of the full range, such as 70 Hz-1.5 KHz.

If a NO branch is taken from the stage 106, then flow 100 may transition to another stage, such as the stage 108 where the signals from the stage 104 may be analyzed (e.g., for level in dB vs. frequency over an entire frequency range of the headset). On the other hand, if a YES branch is taken from the stage 106, then flow 100 may transition to another stage, such as the stage 110 where signals from the leakage transducer(s) may be analyzed at one or more specific frequencies and/or frequency ranges (e.g., for level in dB vs. frequency for those specific frequencies and/or frequency ranges).

At a stage 112 a decision may be made as to whether or not to modify the audio signals that are being driven on the headset transducer(s) based on the analyzing at the stage 108 or at the stage 110. If a NO branch is taken from the stage 112, then flow 100 may transition to another stage, such as the stage 104, for example. However, if a YES branch is taken from the stage 112, then flow 100 may transition to another stage such as a stage 114, for example.

At the stage 114 a decision may be made as to whether or not to apply either active noise cancellation (ANC) or active leak paths (ALP), or both, in the modifying of the audio signals. ANC and ALP will be described in greater detail below. If a YES branch is taken from the stage 114, then flow 100 may transition to another stage, such as the stage 116 where ANC data, ALP data or both may be applied in a calculus for modifying the audio signals. As one example, the leakage transducers may generate signals indicative of the leakage of sound generated by a loudspeaker of the headset and the signal may also be indicative of external ambient noise that leaks into a portion of the headset via one or more leakage paths. Therefore, the signals being sensed from the leakage transducers may include leakage from the loudspeaker plus ambient noise. In other examples, the signals being sensed from the leakage transducers may include leakage from the loudspeaker only (e.g., sans ambient noise). Active noise cancellation algorithms and/or circuitry may be employed to subtract or otherwise remove or reduce the ambient noise component of the sensed signals from the leakage transducers. Separate transducers for sensing the ambient noise may be used and signals from those separate transducers may be processed to generate ANC data (e.g., in analog and/or digital form) to be applied in a calculus (e.g., processing by algorithms and/or circuitry) to modify the audio signals to compensate for the leakage.

As another example, transducers may be positioned in one or more portions of a headset in which active leakage paths are formed. Each active leakage path may include one or more transducers (e.g., a microphone or an accelerometer) and one or more valves and/or variable apertures that may be controlled by a signal (e.g., a voltage or current) applied to the valve(s). Opening the valve(s)/aperture(s) may allow sound generated by a loudspeaker of the headset to intentionally leak from the headset and stimulate the transducer positioned in the active leakage path. A signal from the one or more transducers may be processed and compared with signals from other leakage transducers (e.g., those not positioned in the active leakage paths) to determine which frequencies and/or ranges of frequencies are affected by the leakage. Those signals may be processed to generate ALP data (e.g., in analog and/or digital form) to be applied in a calculus (e.g., processing by algorithms and/or circuitry) to modify the audio signals (e.g., frequency equalization) to compensate for the leakage. In some examples, a transducer positioned in an active leakage path may also serve as a transducer for active noise cancellation (ANC). If a NO branch is taken from the stage 114, then flow 100 may transition to another stage, such as a stage 118, for example.

At the stage 118, modified audio signals may be driven on the headset transducers to compensate for the leakage. Modifying of the audio signals may include applying equalization to one or more frequencies and/or frequency ranges of the audio signals. Equalization may include boosting and/or attenuating the audio signals in those one or more frequencies and/or frequency ranges. Modifying of the audio signals may include applying the ANC data from the stage 116 to remove, reduce or otherwise subtract out effects of ambient noise present in the sensed signals (e.g., sensed by the leakage transducers) at the stage 110. The applying of the ANC data may occur before, after, or contemporaneously with other processing (e.g., equalization) used in modifying the audio signals. Modifying may include varying a damping factor of an amplifier coupled with the headset loudspeaker(s) to alter a low frequency behavior of the headset loudspeaker(s), such as increasing the damping factor to garner greater control of motion of the headset loudspeaker(s) at low frequencies (e.g., back and forth excursions of cone or motive element of the loudspeaker at low frequencies) to improve low frequency response, to improve articulation of low frequency information (e.g., bass notes in music and/or speech), just to name a few for example.

At a stage 120 a decision may be made as to whether or not flow 100 is completed (e.g., done). If a YES branch is taken from the stage 120, then flow 100 may terminate. Conversely, if a NO branch is taken from the stage 120, then flow 100 may transition to another stage, such as the stage 104 were signals from the leakage transducers may continue to be sensed. The NO branch may include a real time and/or continuous sensing of the leakage transducers to continually apply the various stages of flow 100 to counteract the effects of leakage during playback of content on the headset.

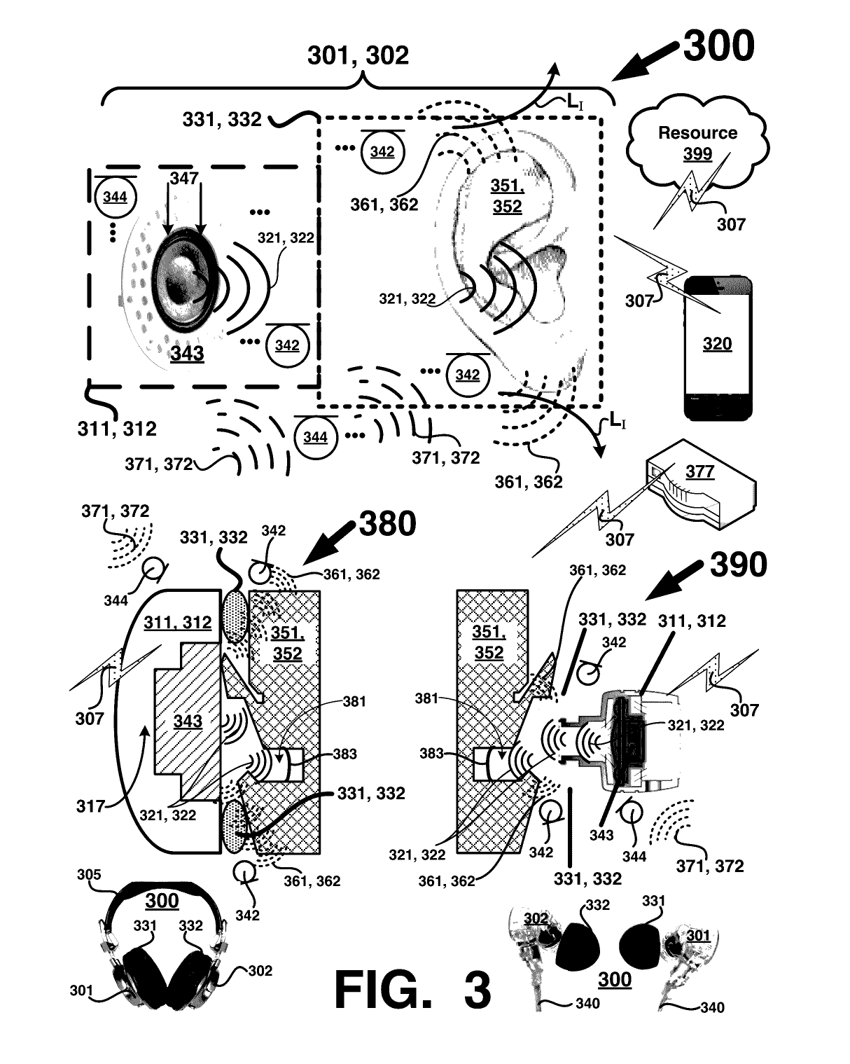

Content (e.g., phone conversations, music, sound or other) being played back on the headset may be communicated to the headset using a hard wired connection, such as a headphone cable or a USB cable, which may include a microphone and headphone controls, and/or by a wireless communications link (e.g., wireless link 307 of FIG. 3) between the headset and an external wireless client device (e.g., wireless client device 320 of FIG. 3) and/or network, such as a smartphone, wireless access point, WiFi, WiMAX, cellular phone, tablet, pad, PC, server, laptop computer, wireless router, WiFi router, gaming device, an external resource such as the Cloud and/or the Internet (e.g., resource 399 of FIG. 3), for example. The wireless communications link may include one or more wireless protocols including but not limited to one or more varieties of IEEE 802.x, Bluetooth (BT), BT Low Energy (BTLE), WiFi, WiMAX, Cellular, Software-Defined-Radio (SDR), HackRF, and Near Field Communication (NFC), AdHoc WiFi, short range RF communication, long range RF communication, just to name a few. One or more radios in the headset may be used for wireless communications with other wireless devices.

The setting of modes (e.g., a leakage detection mode, an ANC mode), execution of commands, processing of signals and/or data (e.g., in flow 100 of FIG. 1) may be accomplished using signals or data communicated to/from the headset via a wired and/or wireless communications link (e.g., a headphone cable, USB cable, wireless link 307 in FIG. 3). Similarly, an external wireless device (e.g., a wireless client such as a smartphone, pad, or tablet) may determine a status of the headset (e.g., status of a power supply, leakage detection mode enabled/disabled, active noise cancellation enabled/disabled, volume levels, equalization, balance, wireless network connections, etc.). As one example, a data packet may include data representing content as a data payload and may include a number of fields, with one or more of the fields including data representing a mode setting.

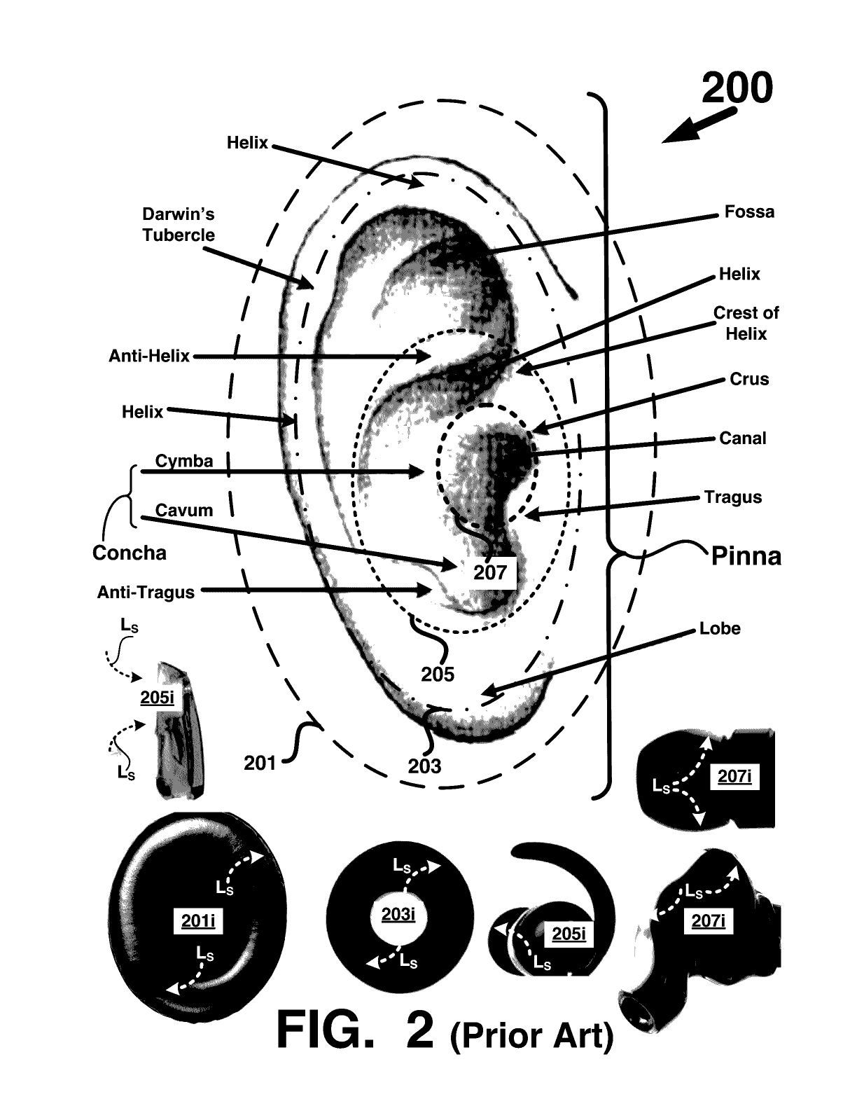

Turning now to FIG. 2 where examples 201i, 203i, 205i, and 207i of conventional ear pads, earbuds, eartips, and ear molds used for a variety of conventional headsets are depicted. In FIG. 2, examples 201i, 203i, 205i, and 207i may correspond to different interface regions of an ear 200 that the ear pads, earbuds, eartips, and ear molds of examples 201i, 203i, 205i, and 207i may interface with when donned by a user and examples of potential leakage paths, denoted as L_{S}, between the interface regions and the donned ear pads, earbuds, eartips, and ear molds of examples 201i, 203i, 205i, and 207i.

A Pinna of ear 200 may include the annotated sections depicted in FIG. 2 (e.g., portions of ear 200 that are visible outside of the human head) such as the Helix, Concha, Tragus, Fossa, Anti-tragus, Lobe, Canal, etc. Interface regions between one or more portions of the Pinna are denoted in dashed line as 201 (e.g., for over-ear headsets using ear pads 201i), 203 (e.g., for on-ear headsets using ear pads 203i), 205 (e.g., for in-ear headsets using earbuds or eartips 205i), and 207 (e.g., for in-ear eartips or ear molds 207i). Sound produced by transducer(s) in the headset coupled with the various examples 201i, 203i, 205i, and 207i may leak from the headset along one or more portions of the interface between the ear pads, earbuds, eartips, and ear molds depicted as denoted by example leakage paths L_{S}. Variations in ear shape, size and ornamentation (e.g., earrings, piercings, etc.) as wells as variations in shape and size in human heads may mean that leakage paths L_{S} for the same type of coupler (e.g., 201i or 205i) may produce different leakage paths L_{S} for different ears on different humans. For example, for an on-ear coupler such as 203i, the leakage paths L_{S} may be different for the same user when user wears an earring in the lobe of the ear vs. not wearing the earring. The effects of the leakage paths L_{S} may include but are not limited to causing frequency response degradation to a frequency response of the headset. A degraded frequency response may cause a loss of low frequency sound (e.g., less bass or a perception of weak bass output from the headset).

Moving now to FIG. 3 where an example of a headset 300 with leakage detection is depicted. Here, headset 300 may include a headphone, an earphone, an earpiece, a wireless headset, a wired headset, a wireless headphone, a wired headphone, or the like. The headset 300 may include a single ear cup or ear bud (e.g., 301 or 302) for one ear (e.g., a mono channel) or two ear cups or ear buds (e.g., 301 and 302) for two ears (e.g., stereo channels) of the user. In FIG. 3, a portion of the headset 300, denoted as 311 and 312 for right and left ears 351 and 352 respectively and another portion of the headset 300 that includes the interface (e.g., a pinna interface) with the right and left ears 351 and 352 (e.g., ear pads, eartips, earbuds, ear molds, etc.) are denoted as 331 and 332. Loudspeaker(s) 343 may be housed in portions (311, 312). Portions (311, 312) may include a housing or other form of enclosure or chassis that may include a chamber or other volume, denoted as 317, in which the loudspeaker(s) 343 are positioned (e.g., an acoustic chamber or acoustic volume). Acoustic chamber 317 may be designed (e.g., by its shape, its volume, its materials, etc.) to produce an audio effect, such as a frequency response, low frequency response, flat frequency response, bass tuning, midrange tuning, etc., just to name a few, for example. Acoustic chamber 317 may include an additional volume that extends into interface (331, 332) in a direction towards ear (351, 352). At least a portion of acoustic chamber 317 may be configured to include an acoustic impedance Z_{A} as seen by loudspeaker 343 when loudspeaker 343 is set in motion by electrical signals from an amplifier electrically coupled with loudspeaker 343. Acoustic impedance Z_{A} may include an acoustic impedance for loudspeaker 343 in an absence of leakage caused by leakage paths as will be described below.

As noted above, there may be only a single sound producing element of the headset 300 (e.g., a single or mono channel), in which case there would be a 311 and 331 for ear 351 or a 312 and 332 for ear 352. Although the description that follows may describe headset 300 as having both left and right side ear cups 301 and 302, the present application is not limited to that configuration and there may be a single ear cup (301 or 302). Moreover, leakage detection, active noise cancellation, and application of feedback or other corrective signals that may be used to compensate and/or remediate the effects of leakage and/or ambient noise may apply in whole or in part to configurations where there may be a single ear cup (301 or 302).

In FIG. 3, headset 300 is depicted with a loudspeaker 343 positioned in the housing and generating sound (321, 322) in response to audio signals applied to nodes 347 of the loudspeaker 343. There may be a single loudspeaker 343 (e.g., a full range driver) or there may be a number of loudspeakers 343, such as a tweeter loudspeaker and a low-midrange loudspeaker, which may be coupled with different amplifiers or may be coupled with a cross-over network (e.g., an active or a passive cross-over) that is coupled with a single amplifier, for example. Here, the interface (331, 332) is coupled with one or more portions of the ears (351, 352) so that sound (321, 322) generated by loudspeaker 343 enters into the ears (351, 352) of the user (e.g., into the canal of the ears).

In some cases the interface (331, 332) may not form a perfect acoustic seal with those portions of the ears (351, 352) it is in contact with. Consequently, leakage paths may be present at one or more locations along the various points of contact between the interface (331, 332) and the ears (351, 352). Accordingly, sound leakage (361, 362) may escape via one or more leakage paths denoted as L_{I}. Leakage paths L_{I} as well as other paths may also allow ambient sound (371, 372) to enter via an air gap or an instance of an opening in a seal between the interface (331, 332) and one or more portions of ears (351, 352).

Transducers 342 (e.g., microphones, accelerometers, piezoelectric devices, etc.) may be positioned at one or more locations in the interface (331, 332) and/or housing (311, 312) to sense energy associated with sound leakage. The transducers 342 may not be positioned at or adjacent to any actual leakage path L_{I} because those paths may change or vary over time, as the interface shifts or otherwise moves relative to ears (351, 352) or may be different each time the headset 300 is donned by the user. Energy sensed by the transducers 342 may include but is not limited to mechanical vibration, acoustic energy, changes in air pressure (e.g., compression and rarefaction in waves of air), changes in air flow rate, or some combination of the foregoing.

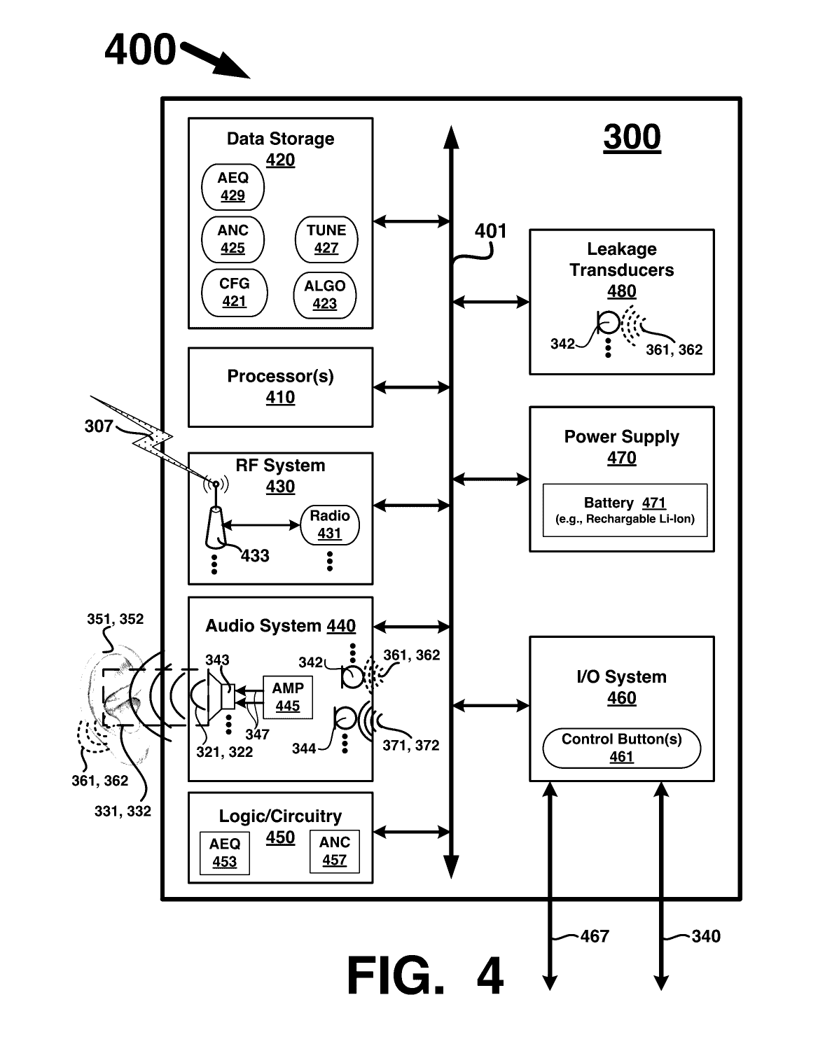

Signals generated by transducers 342 may be processed, analyzed or otherwise handled by hardware and/or software (e.g., active equalization AEQ algorithm(s) 429 of FIG. 4), and a result from the processing/analyzing may be used to modify audio signals being driven onto nodes 347 (e.g., speaker terminals) of loudspeaker 343 (e.g., by amplifier 445 of FIG. 4). Modifying the audio signals may include boosting or cutting sound level (e.g., in dB) of one or more frequencies and/or frequency bands in the audio signal. For example, leakage paths L_{I} may affect low frequency response of headset 300 by causing a fall-off in a frequency response profile for headset 300, such that low frequency output of loudspeaker 343 drops faster (e.g., is attenuated or dips) as a function of frequency at a low frequency region of a frequency response profile for the headset 300 (e.g., from about 20 Hz to about 150 Hz). This dip in low frequency response may be adjusted upward at one or more frequencies and/or frequency ranges by applying frequency equalization at the one or more frequencies and/or frequency ranges using hardware (e.g., AEQ 453) and/or software (e.g., AEG 429), for example. As another example, leakage paths L_{I} may affect tuning of the loudspeaker 343 by changing the acoustic load seen by the loudspeaker 343 as it moves back and forth in response to audio signals. In some cases a bass response may be perceived, from the perspective of a user, for example, to be loose or lacking in punch or pitch definition. Circuitry and/or software may be used to adjust tuning of the loudspeaker 343 to adjust or eliminate effect of sound leakage on tuning of the loudspeaker 343. As one example, a damping factor an amplifier that drives the audio signals (e.g., AMP 445 of FIG. 4) may be increased or decreased to affect low frequency behavior of loudspeaker 343. For example, the damping factor may be increased to improve control of the loudspeaker 343 at low frequencies (e.g., from about 20 Hz to about 200 Hz). As the damping factor is increase, greater control of back and forth excursions of a cone or motive element of loudspeaker 343 may occur with a resulting improvement in bass sound (e.g., pitch definition, low frequency articulation, etc.).

In that ambient sound from an environment external to the headset 300 may be sensed by transducers 342, another transducer(s) 344 may be positioned at one or more locations in the interface (331, 332) and/or housing (311, 312) to sense energy associated with ambient sound. Energy sensed by the transducers 344 may include but is not limited to mechanical vibration, acoustic energy, changes in air pressure (e.g., compression and rarefaction of air), or some combination of the foregoing. For example, transducers 344 may include microphones, accelerometers, piezoelectric devices, etc., just to name a few. Signals generated by transducers 344 may be processed, analyzed or otherwise handled by hardware and/or software (e.g., ANC algorithm(s) 425 of FIG. 4), and a result from the processing/analyzing may be used to reduce or eliminate a component of the ambient sound that is sensed by transducers 342. As one example, sound leakage sensed by transducers 342 may be regarded as the signal (e.g., from loudspeaker 343) and ambient sound sensed by transducers 344 may be regarded as a source of noise. The processing/analyzing may be used to increase a signal-to-noise ratio of the signals from the transducers 342 by eliminating or reducing the noise from the ambient sound. Transducers 344 may also be used for implementation of an active noise cancellation mode of operation for headset 300 (e.g., for sealed or closed back headsets 300).

In FIG. 3, examples 380 and 390 depict different headset configurations, with example 380 depicting an over-ear headset 300 having an interface (e.g., ear pads) (331, 332) positioned in contact with ear (351, 352). Here, a headband 305 may position ear pads 331 and 332 of the right and left ear cups 301 and 302 respectively, onto their respective ear (351, 352). Sound 321, 322 generated by loudspeaker 343 enters into ear canal 381 and impinges on ear drum 383; however, some of that sound (361, 362) exits the interface (331, 322) along one or more leakage paths L_{I} as described above. Transducers 342 may be positioned at one or more locations to capture the sound (361, 362). Similarly, ambient sound (371, 372) incident on headset 300 may be captured by one or more appropriately positioned transducers 344.

In example 390, headset 300 may include an in-ear design in which at least a portion of the interface (331, 332) (e.g., an ear tip) is inserted into the concha and/or canal 381 of the ear (351, 352). Sound generated by audio signals applied to loudspeaker 343 may enter into canal 381 and impinge on ear drum 383, but as above, some of that sound may exit (361, 362) the interface (331, 332) along one or more leakage paths L_{I} as described above. As mentioned above, transducers 342 may be positioned at one or more locations to capture the sound (361, 362). Similarly, ambient sound (371, 372) incident on headset 300 may be captured by one or more appropriately positioned transducers 344.

In examples 380 and 390, the transducers depicted are positioned to illustrate relative positions at which they may be disposed to receive sound, vibration, mechanical energy, air pressure changes, changes in rate of air flow, etc. Actual positions may be application dependent and the transducers may be disposed at one or more locations in or on structure of headset 300, such as in housing (311, 312) and/or in interface (331, 332), for example.

In FIG. 3, content, data, commands, control and other headset functions may be wirelessly communicated to the headset 300 using a wireless communications link 307, and/or may be communicated via a wired link (e.g., headset cord 340). The content, data, commands, control and other headset functions may be wirelessly communicated from an external source, such as resource 399 (e.g., the Cloud, the Internet, a web site, a web page, data storage, NAS, RAID, a server, a PC, a laptop, a router, a wireless client device, etc.) or from a wireless client device 320 (e.g., a smartphone, smart watch, wearable device, wearable electronics, gaming device, tablet, pad, etc.).

Reference is now made to FIG. 4 where one example of a block diagram 400 for headset 300 is depicted. Systems and components of the headset 300 may be electrically coupled with each other using a bus 401 or other electrically conductive structure for electrically communicating signals. Some portions of headset 300 may be duplicated in both ear cups (e.g., 301 and 302) of the headset 300. Headset 300 may have systems including but not limited to: a processor(s) 410; data storage 420; a RF system 430; an audio system 440; logic/circuitry (e.g., analog and/or digital) 450; an I/O system 460; a power supply 470, and leakage transducers 480. Leakage transducers 480 may include or be coupled with one or more transducers 342. In other examples, some or all of those transducers 342 may be disposed in another system, such as the audio system 440.

Processor(s) 410 may include one or more compute engines and the processor(s) 410 may execute algorithms and/or data embodied in a non-transitory computer readable medium, such as algorithms (ALGO) 423, configuration file (CFG) 421, active noise cancellation (ANC) algorithms denoted as ANC 425, audio tuning algorithms TUNE 427 (e.g., general headset equalization to suit user tastes), and active equalization AEQ 429 algorithms (e.g., equalizing frequency response due to sound leakage, adjusting damping factor of AMP 445, etc.). One or more of the algorithms executed by processor(s) 410 may reside in data storage 420 as depicted, or may reside in an external non-transitory computer readable medium (e.g., resource 399 and/or client device 320). In some examples, the algorithms may be executed by an external compute engine, such as a server, client device 320, or resource 399. Processor(s) 410 may include but are not limited to one or more of a processor, a controller, a μP, a μC, a DSP, a FPGA, and an ASIC, for example. Data storage 420 may include one or more types of electronic memory such as Flash memory, non-volatile memory, RAM, ROM, DRAM, and SRAM, for example. Configuration (CFG) 421 may include data including but not limited to access credentials for access to a network such as wireless link 307, a WiFi network, a Bluetooth network, MAC addresses, Bluetooth addresses, data used for configuring the headset 300 to recognize and/or link with other wireless devices without intervention on part of a user, to determine a type of radio and/or a wireless protocol (e.g., BT, BTLE, NFC, WiFi, etc.) to use for one or more wireless links (e.g., 307 of FIG. 3), for example.

RF system 430 may include one or more antennas 433 coupled with one or more radios 431. The wireless link 307, between the headset 300 and other wireless devices may be handled by the same or different radios 431. Different radios 431 may be coupled with different antennas 433 (e.g., one antenna for NFC and another antenna for WiFi).

I/O system 460 may include a port 467 for a wired connection with an external device such as an Ethernet network, USB port, a charging device for charging a rechargeable battery in power supply 470, for example. As one example, port 467 may include a micro or mini USB port for wired communication between the headset 300 and an external device and/or between the headset 300 and an external charging device, such as a charger the hybrid headphone docks with or an AC or DC charger. I/O system 460 may also include a hardwired connection 340 that may be removable from the headset 300 (e.g., a captive or removable headphone cable with or without microphone and/or audio or other controls). For example, a DIN, mini-DIN, XLR, USB, micro USB, mini USB, TRS, TRRS, 3.5 mm plug, ¼ inch plug or the like, may be removeably coupled with the headset 300 (see 340 in FIG. 3). I/O system 460 may include control buttons 461, such as volume up/down, mute, play, pause, FF, FR, skip track, advance/go-back one track, wireless pairing (e.g., Bluetooth paring), just to name a few, for example.

Power supply 470 may source one or more voltages for systems in the headset 300 and may include a rechargeable power source denoted as battery 471, such as a Lithium Ion type of battery, for example. Battery 471 may be recharged by an external source via port 467.

Audio system 440 may include a number of transducers and their associated amplifiers, preamplifiers, and other circuitry (e.g., ADC, DAC, analog and/or digital circuitry). The transducers may include one or more loudspeakers 343 which may be coupled with one or more amplifiers 445 which drive signals 347 to loudspeaker 343 to generate sound 321, 322 that is acoustically coupled into ears (351, 352) of a user (not shown). Multiple loudspeakers 343 may be used, to reproduce different frequency ranges (e.g., bass, midrange, treble), for example, and those multiple loudspeakers 343 may be coupled with the same or different amplifiers 445 (e.g., bi-amplification, tri-amplification).

The transducers may also include one or more microphones 342, 344 or other types of transducer that may convert mechanical energy (e.g., vibrations, sound waves from ambient sound and/or speech) into an electrical signal. A number of the microphones 342, 344 may be configured into a microphone array or other configurations. The transducers may include accelerometers, motion detectors, piezoelectric devices, or other type of transducer operative to generate a signal from motion, pressure changes, mechanical energy, etc. Microphones 342, 344 or other type of transducers may be coupled with appropriate circuitry (not shown) such as preamplifiers, analog-to-digital-converters (ADC), digital-to-analog-converters (DAC), DSP's, analog and/or digital circuitry, for example. The appropriate circuitry may be included in audio system 440 and/or other systems such as logic/circuitry 450 (e.g., circuitry for active equalization 453, active noise cancellation system ANC 457). Processor(s) 410 may execute one or more algorithms (e.g., machine executable instructions in CFG 421, ANC 425, AEQ 429, TUNE 427, ALGO 423) separately or in conjunction with hardware, circuitry, or logic such as in logic/circuitry 450 and/or audio system 440, for example. Transducer 342 (e.g., one or more microphones) may be operative to receive sound (321, 322) generated by loudspeaker 343 and transducer 344 (e.g., one or more microphones) may be operative to receive sound (361, 362) generated by ambient sound in an environment around headset 300. Signals from transducers 342 and/or 344 may be used for active equalization (AEQ) to counteract the effects of sound leakage on audio quality (e.g., frequency response), active noise cancellation (ANC) to increase a signal-to-noise (S/N) ratio in processing of signals from transducers 342, for example. Signals from transducers 342 and 344 may be processed by circuitry and/or algorithms to implement the AEQ and ANC modes.

Headset 300 (e.g., examples 380 and 390 of FIG. 3) may include right 301 and left 302 ear cups (e.g., example 380 of FIG. 3) or earpieces (e.g., example 390 of FIG. 3) and some systems depicted in block diagram 400 of FIG. 4 may be included (e.g., duplicated) in each ear cup (301, 302), such as audio system 440, power supply 470 and/or battery 471, processor(s) 410, or other systems. Each ear cup (301, 302) may include its own dedicated transducers (342, 344). Circuitry for processing signals from transducers (342, 344) may be positioned in one or both ear cups, or some other location in headset 300, such as the headband 305, for example.

Headset 300 may be wirelessly linked with one or more external wireless devices including but not limited to a smartphone (e.g., client device 320), a wireless network, a WiFi network, a wireless router (e.g., 377), a Bluetooth network, a Bluetooth Low Energy network, the external resource 399 (e.g., the Cloud, Cloud storage, the Internet, NAS, RAID, server(s), a wearable electronic device, a wireless speaker box, a smart watch, etc.). Those external wireless devices may serve content and/or provide access to content from another device(s), exercise command and/or control of headset 300, and may process data and/or signals (e.g., transducer signals) from the headset 300 (e.g., in flow 100 of FIG. 1.).

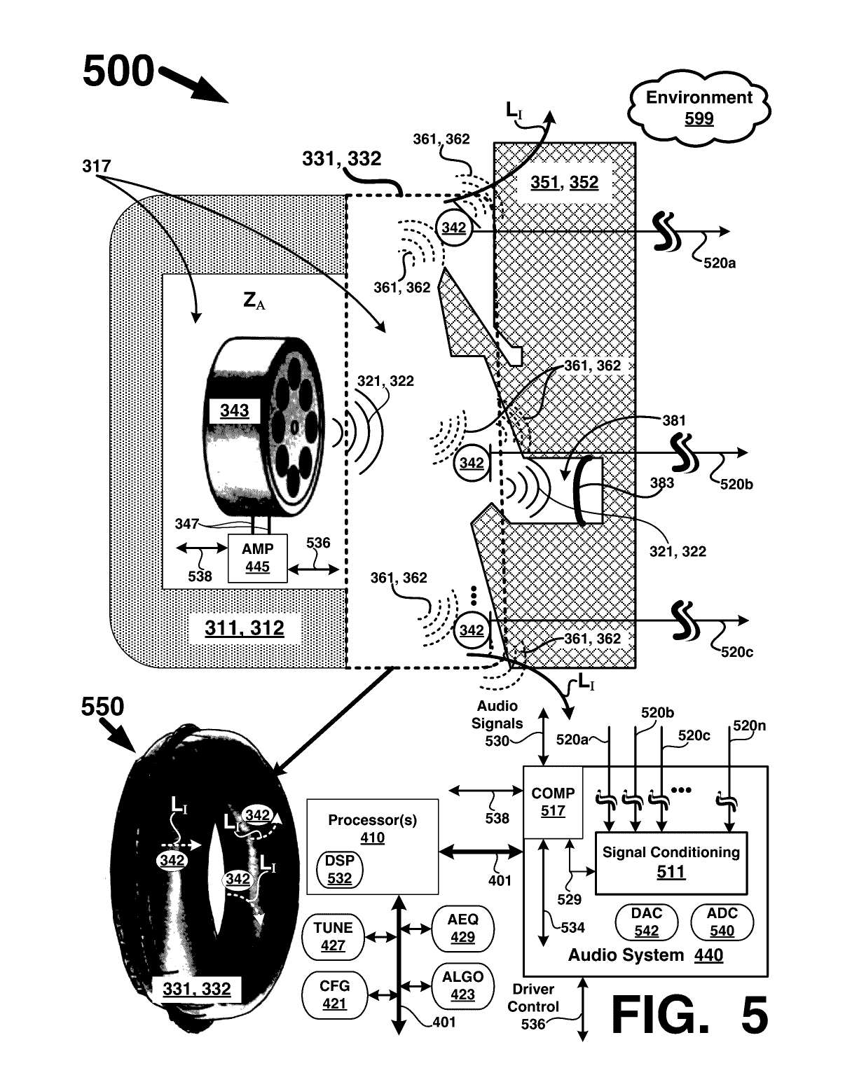

Referring now to FIG. 5 where examples of a cross-sectional view 500 of a headset 300 with leakage detection and of a block-diagram of hardware and/or software that may be used to implement leakage detection and correction are depicted. The examples of FIG. 5 includes an example type of interface in the form of an ear pad (331,332) for an over-ear type of headset, however, the present application is not limited to the structure depicted in FIG. 5 and other types of interfaces may be used, such as ear-tips, on-ear, in-ear, ear molds, earbuds, etc. In the cross-sectional view depicted, a portion (311, 312) of the headset 300 (e.g., a mono channel or one-half of a stereo channel) is depicted with its interface (331, 332) coupled with an ear (351, 352) of a user (not shown). Here, headband 305 of FIG. 3 may be used to assist in positioning the portion (311, 312) and its associated interface (331, 332) with respect to the ear (351, 352). Sound (321, 322) generated by loudspeaker 343 enters canal 381 and impinges on ear drum 383; however, a portion of the sound (321, 322) may escape, leak or otherwise exit along one or more locations between interface (331, 332) and ear (351, 352) or other portion of the user's head as sound leakage (361, 362) denoted as the leakage paths L_{I}. The leakage paths L_{I} depicted are examples only and there may be more or fewer leakage paths L_{I}. In some examples, a quantity, a size and other characteristics of the leakage paths L_{I} may dynamically change as the portion (311, 312) and/or interface (331, 332) shifts position relative to the ear (351, 352) or some other surface or structure on a head of the user and/or the user's pinna. Motion, vibration, head movement, body movement (e.g., exercise), condition of the interface (331, 332) (e.g., new or worn out), age of the interface (331, 332) (e.g., aging of materials such as foam, rubber, synthetics, etc.), ambient temperature in an external environment 599, type of interface (331, 332), etc. may have an effect on the number and locations of the leakage paths L_{I}. Depending on volume levels of sound (321, 322), the sound leakage (361, 362) may be audibly perceptible to persons (not shown) in the external environment 599 around the user.

One or more transducers 342 (e.g., microphones, piezoelectric devices, accelerometers, etc.) may be positioned at one or more locations on portion (311, 312), such as interface (331, 332), acoustic chamber 317, or other location, for example. Transducers 342 may be embedded in, positioned on, or otherwise coupled with portion (311, 312) and/or interface (331, 332) and may be electrically coupled via conductive paths 520a-520n with circuitry in audio system 440, such as signal conditioning circuitry that may include a preamplifier for increasing a magnitude of signals on conductive paths 520a-520n, for example. Example 550 depicts an example of transducers 342 disposed in interface (331, 332) to detect sound leakage paths L_{I} along different portions of the interface (331, 332). For example, positions of one or more transducers 342 may be selected based on empirical data for where leakage of sound may likely occur between interface (331, 332) and ear (351, 352) and its surrounding pinna for the type of interface (331, 332) being used (e.g., over-ear, on-ear, in-ear, ear bud, eartips, ear mold, etc.). The empirical data may be collected over a statistically relevant sampling of various male and female human head and ear types to account for differences in ear/pinna structure, head sizes, shapes, etc., for example.

Signal conditioning 511, if implemented, may output conditioned signals that may be processed by hardware and/or software in audio system 440 and/or other systems (e.g., one or more systems in block diagram 400 of headset 300 in FIG. 4). The hardware and/or software may include but is not limited to an analog-to-digital converter (ADC) 540, a digital-to-analog converter (DAC) 542, a digital-signal-processor (DSP) 532, processor(s) 410, tuning algorithm TUNE 427, equalization algorithm AEQ 429, configuration algorithm CFG 421, and algorithm ALGO 423, active noise cancellation ANC 425, for example. ALGO 423 may include one or more executable program codes used by headset 300 for purposes including but not limited to operation of headset 300, implementing one or more stages of flow 100, processing of data, processing of signals, wireless communication 307, just to name a few, for example. Software (e.g., algorithms, firmware, operating system (OS), etc.) may be accessed by processor 410 and/or DSP 532 from data storage 420 via bus 401, for example.

As one example, signals on conductive paths 520a-520c may be processed by audio system 440 or other systems in headset 300. Processing may include comparing (e.g., in COMP 517) the signals on conductive paths 520a-520c (e.g., generated by transducers 342 from sound 361, 362 associated with leakage paths L_{I}) with audio signals 530 that are coupled with AMP 445 and subsequently driven via nodes 347 to loudspeaker 343 (e.g., audio content received by headset 300 via wireless 307 and/or wired 340 link). The comparing may be used to adjust the sound generated by loudspeaker 343 by generating a modified audio signal 534 and electrically coupling the modified audio signal 534 with AMP 445 via conductive path 538. Modified audio signal 534 may be coupled with other circuitry in headset 300. The audio signals 530 as received by the headset 300 may initially be coupled with AMP 445 (e.g., via conductive path 538) and be uncorrected for effects of sound leakage (361, 362) during a signal processing latency of the one or more systems in headset 300 (e.g., in block diagram 400 in FIG. 4). Subsequently, the modified audio signals 534 may be coupled with AMP 445 (e.g., via conductive path 538) in place of audio signals 530 as a result of the processing of signals including but not limited to signals on conductive paths 520a-520c. A feedback loop may be used to adjust (e.g., actively, dynamically, in real-time, periodically, etc.) for effects of sound leakage (361, 362). Modified audio signal 534 may be generated as an output signal from hardware and/or algorithmic processing of signals including but not limited to audio signals 530 and signals 520a-520c associated with leakage paths L_{I}, for example. COMP 517 and/or signal conditioning 511 may be included in audio system 440 or in some other system of headset 300, such as logic/circuitry 450 or AEQ 453, for example. Modified audio signal 534 may be operative to alter or otherwise adjust an acoustic impedance of acoustic chamber 317 so that it more closely matches an acoustic impedance (e.g., Z_{A}) acting on loudspeaker 343 in an absence of the leakage paths L_{I}.

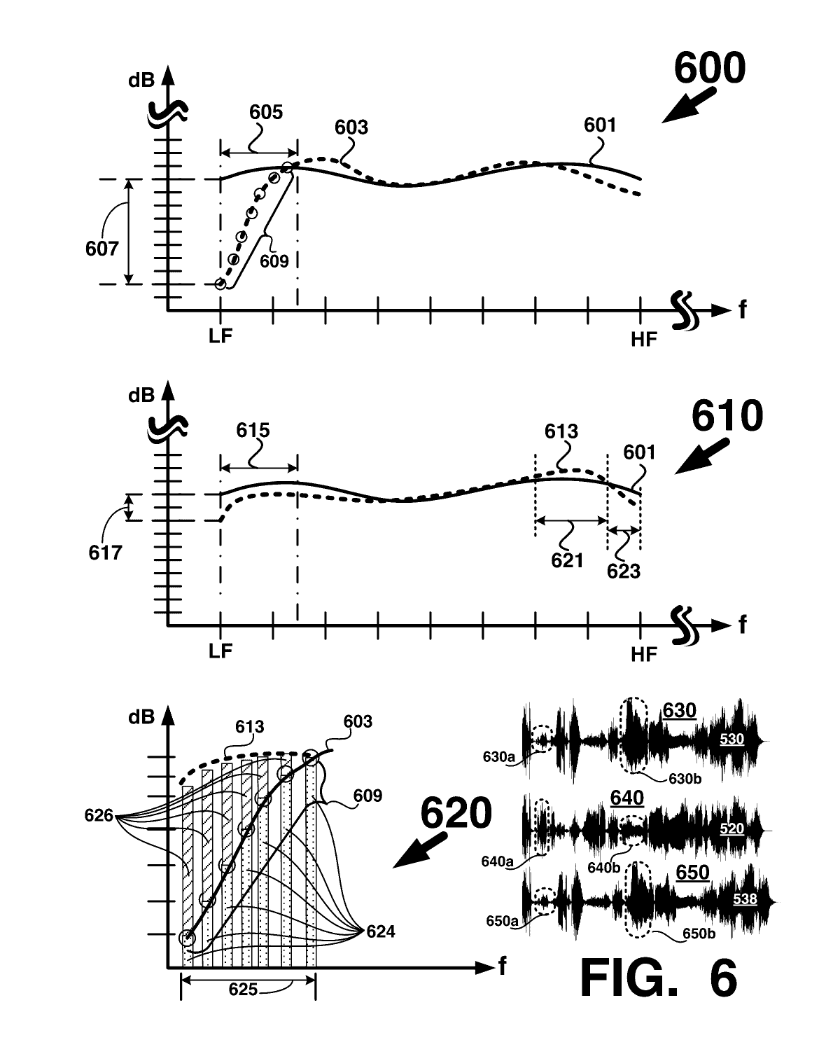

Moving on to FIG. 6 where various examples 600, 610 and 620 of frequency response profile (e.g., a profiled relationship between frequency and sound pressure level in dB's) and audio signals 620, 640 and 650 for a headset 300 with leakage detection are depicted. In example 600 a frequency response profile that spans a relatively low frequency LF (e.g., about 20 Hz) to a relatively high frequency HF (e.g., about 20 kHz) range of headset 300 may include a preferred or preferred frequency response profile denoted as 601; however, due to sound leakage (361, 362) associated with one or more leakage paths Los described above in reference to FIGS. 3-5, an actual frequency response profile denoted as 603 may include dips or bumps in frequency response due to sound leakage. Here, profile 603 includes a low frequency fall-off within a range 605 in the LF region, such that at several points within that region 605, there may be a decibel reduction in sound level denoted as 607 when compared to profile 601. Systems in headset 300 may sample one or more points in the affected frequency range or ranges as denoted by a number of sample points 609 which may indicate a number of points along profile 603 in the LF region where there is a dB reduction in sound level at various low frequencies. Although the example 600 depicts a low frequency drop off in sound level, the present application is not limited to the examples depicted herein and other frequency ranges and/or frequencies may be affected by sound leakage (361, 362), such as at the HF region, for example.

In real-time, dynamically, or at some other interval, systems in headset 300 may analyze signals (e.g., transducer signals 520a-520n) to detect and adjust effects of sound leakage (361, 362). As one example, one or more of signal conditioning 511, comparing 517, processing via flow 100, application of one or more algorithms (e.g., 427, 425, 429, 423, 421, etc.), processing via hardware/circuitry (e.g., 410, 532, 450, etc.) may be used to generate the above mentioned modified audio signal 548 that is applied to loudspeaker 343 to produce a modified frequency response profile 613 that may more closely match the preferred or target frequency response profile 601 as depicted in example 610. In some cases, the modified frequency response profile 613 may not be identical to the profile 601 and may still include some regions of frequency dips or bumps, such as in region 615 where there may be a frequency dip denoted by 617. However, the dip at 617 is less than the dip at 607 of example 600. There may be other regions of frequency anomalies in the frequency response profile 613, such as a slight bump 621 (e.g., a rise in sound level) followed by a slight dip 623 (e.g., a reduction in sound level) in the HF region of example 610. Systems in headset 300 may adjust one or more anomalies in frequency response due to sound leakage (361, 362), such as those in the LF region, the HF region or both. Other regions may also have anomalies, such as a midrange region, upper midrange region, lower midrange region, etc., and those regions or others may be acted on by systems in headset 300 to adjust anomalies in frequency response due to sound leakage (361, 362).

In example 620, profile 613 may be generated by processing the sample points 609 to determine a decibel level 624 for each of the sampled frequencies in the sample points 609 along the profile 603. Here, seven frequencies points in range 625 are sampled, each point having its own respective decibel level 624. Processing (e.g., in a DSP) may determine that some or all of the sampled points 609 require a boosting of their decibel level as denoted by boost level 626. For example, the lowest frequency within range 625 may require the largest boost level 626, with increasing higher frequencies within range requiring increasing smaller boost levels 626 as depicted in example 620 where from left to right within range 625 six of the seven points in range 625 have their decibel levels boosted. Here, the boosted levels 626 approximate the profile 613 of example 610, that is, profile 613 is closer to profile 601 than the 603 that exhibited the low frequency fall-off due to sound leakage (361, 362). In other examples, a frequency or range of frequencies may be cut (e.g., reduced in level), boosted (e.g., increased in level) or both to generate the modified audio signal on conductive path 538. In other examples a frequency or range of frequencies may remain un-altered in the modified audio signal on conductive path 538. Un-altered frequencies may or may not conform to the preferred or target frequency response. The preferred or target frequency response (e.g., profile 601) may be a flat frequency response, may be a user-preferred frequency response (e.g., enhanced or exaggerated low frequency boost-bass boost), or some other frequency response.

Although examples 600-620 have depicted dB level vs. frequency and boost as one method of generating the modified audio signal on conductive path 538, the present application is not limited to the examples depicted. Other examples may use frequency cut, or frequency boost and cut at one or more frequencies and/or frequency ranges. In examples 630-650, systems of headset 300 may analyze audio signals 530, analyze signals 520 from sound leakage (361, 362) (e.g., 520a-520n), compare the analyzed signals (e.g., in COMP 517) and generate modified signals on conductive path 538. Signal analysis may occur in the analog domain, the digital domain or both. Comparing may include determining differences in amplitude vs. frequency between audio signals 530 and signals 520 to generate the modified audio signals on conductive path 538. The modified audio signals on conductive path 538 may be generated to more closely match the audio signals 530 (e.g., the input audio data for content being played back on headset 300). For example, audio signals 530 may include a low frequency region 630a and mid-frequency region 630b having the waveforms depicted in example 630; whereas, as a result of sound leakage (361, 362), signals 520 may include different waveforms in corresponding regions 640a and 640b. Processing (e.g., in a DSP) of signals 530 and 520 may be used to detect differences in the amplitudes or other parameters of the audio waveforms to generate the modified audio signal on conductive path 538 having low and mid-frequency regions 650a and 650b that more closely match the regions 630a and 630b, respectively of the audio signals 530.

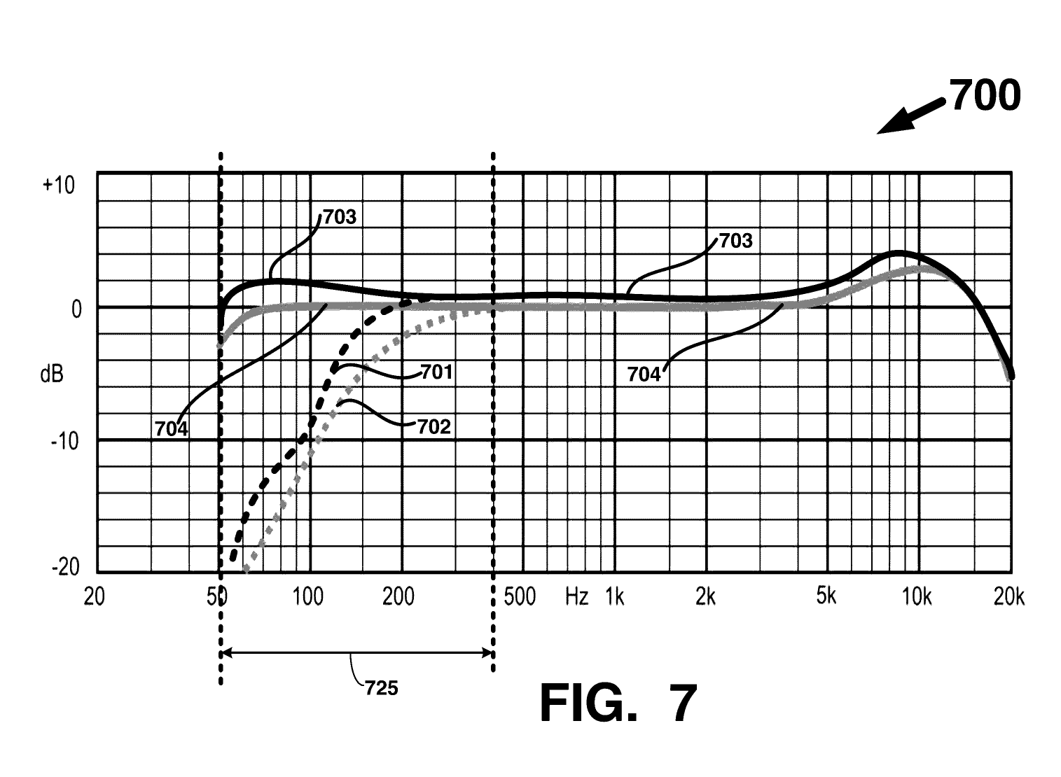

Reference is now made to FIG. 7 where an example 700 of frequency response profiles for a first channel and a second channel of a headset with leakage detection are depicted. Here, within a region 725 there may be a low frequency drop (e.g., in dB's) as function of frequency denoted by dashed portions 701 and 702 for a first channel and second channel of the headset 300, for example. The first channel 701 may be a right channel for the right ear and the second channel 702 may be a left channel for the left ear, for example. Portions 701 and 702 may denote deviations in frequency response due to sound leakage (361, 362) in the right and left channels (701, 702); whereas, profiles 703 and 704 may denote the modified audio signal on conductive path 538, where dB levels in the region 725 (e.g., from about 50 Hz to about 400 Hz) have been modified to reduce the low frequency drop-off due to sound leakage (361, 362). In example 700, a coupling between the interface (331, 332) with a surface of, or adjacent to, their respective ears (351, 352) may cause differences in the signals 520 and the modified signals on conductive path 538 for the right and left channels (701, 702). For example, an ear pad or ear bud 332 on the left ear 352 may have different locations for its leakage paths L_{I} and may have more or fewer leakage paths L_{I} than an ear pad or ear bud 331 on the right ear 351. Accordingly, there may be differences in signals 520 and signals on conductive path 538 due to differences in sound leakage (361, 362) between the left and right ears, for example, thus there may be differences in the frequency response profiles (701, 703) and (702, 704). Systems in headset 300 may process signals 530 and 520 differently for different channels (e.g., right and left channels) and may generate different modified audio signals on conductive path 538 for a single channel (e.g., mono) or multiple channels (e.g., stereo). Audio system 440 may adjust volume levels differently for different channels (e.g., a different balance for right and left channels) such that a volume level in one channel may be the same, higher or lower than a volume level in another channel, for example.

The region 725 of FIG. 7 is just one non-limiting example of one or more regions in a frequency response profile that may have frequencies within the range boosted and/or cut in dB levels to counteract effects of leakage paths L_{I} in headset 300. Other frequency regions and/or discrete frequencies may analyzed and acted upon by systems in headset 300, such as high frequencies and midrange frequencies, just to name a few. Systems in headset 300 may operate continuously, intermittently, or on some predetermined schedule to analyze effects of leakage paths L_{I} and take action to adjust those effects. Although dB levels have been used to describe one aspect of modifying the frequency response profile, the present application is not limited to the example 700 and other forms of frequency response manipulation to adjust effects of leakage paths L_{I} may include but are not limited to modifying a dampening factor of AMP 445 using a loudspeaker control signal 536 from audio system 440 to alter an internal output impedance of the AMP 445, adjusting one or more cross-over frequencies of a cross-over network (e.g., implemented in the analog domain (using a L-C-R network) and/or digital domain (using DSP and/or algorithms)).

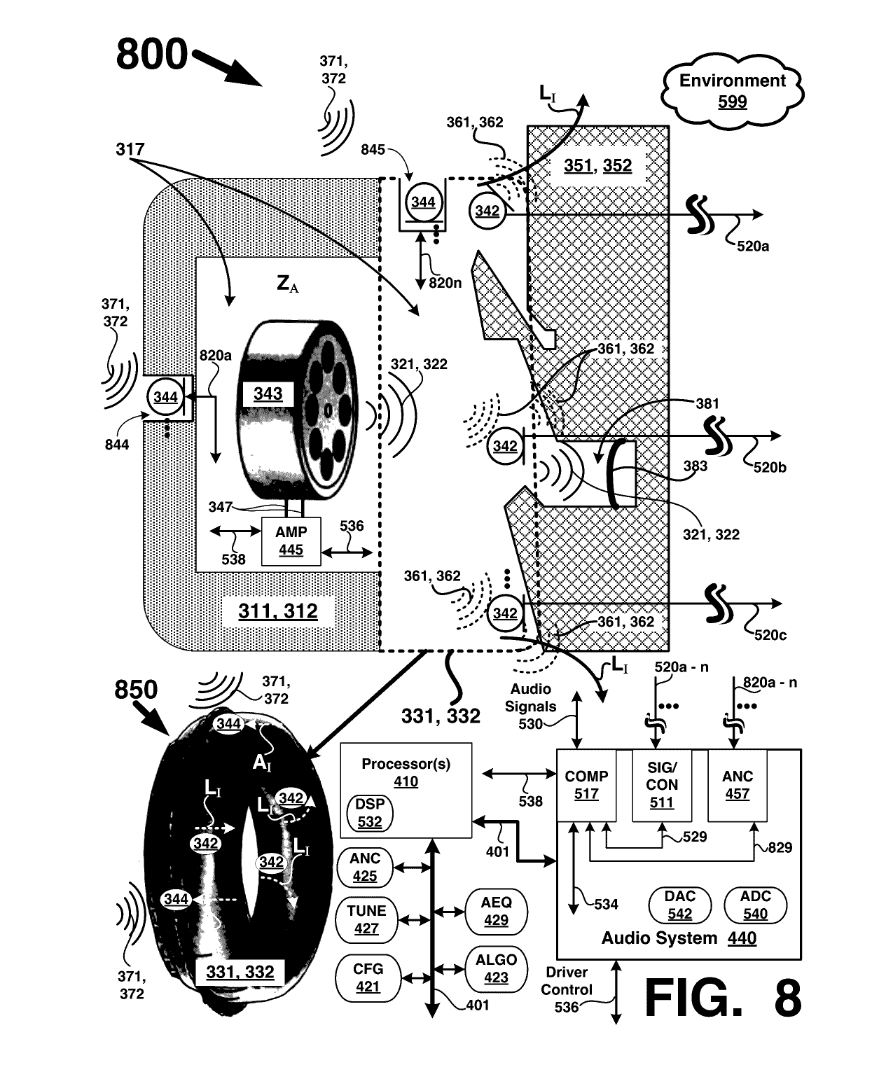

Attention is now directed to FIG. 8 where examples 800 of a cross-sectional view of a headset 300 with leakage detection and automatic noise cancellation and of a block-diagram of hardware and/or software that may be used to implement leakage detection, leakage correction and automatic noise cancellation are depicted. In FIG. 8, headset 300 may include one or more transducers 344 that may be coupled 820a-820n with the automatic noise cancellation system 457. Transducers 344 may include but are not limited to microphones, accelerometers, motion detectors, vibration detectors, and piezoelectric devices, for example. Transducers 344 may be positioned at one or more locations on headset 300. For example, housing (311, 312) may include an opening, portal, aperture, well, hole or the like, denoted as 844 in which one or more transducers 344 may be positioned. As another example, interface (331, 332) may include an opening, portal, aperture, well, hole or the like, denoted as 845 in which one or more transducers 344 may be positioned. Transducers 344 may be disposed in a pattern such as an array for example. Transducers 344 may be positioned in headset 300 in one or more locations suitable for capturing ambient noise (371, 372) in the environment 599, such as at least one transducer 344 on a right side of the headset 300 and at least one other transducer 344 on a left side of the headset 300, for example. Other example locations include but are not limited to the headband 305, an in-line control for the headset, a boom microphone structure, just to name a few.

The ANC system 457 may be coupled 820a-820n with output signals from the transducers 344 and may process those signals using hardware, software or both to generate an output signal 829 that may be compared or otherwise analyzed with other signals, such as the signal 529 to determine an ambient noise component of the sound detected by transducers 342. For example, COMP 517 may be coupled (529, 829) with signals outputted by ANC 457 and signal conditioner SIG/CON 511 and may process those signals to extract out ambient noise (371, 372) that may be present in the sound leakage (361, 362) signals. A signal-to-noise (S/N) ratio of the modified audio signal 534 may be improved by attenuating, stripping out, eliminating, reducing or otherwise identifying the sound leakage (361, 362) in the presence of ambient noise (371, 372) that may be incorporated in the sound leakage (361, 362) signals. Algorithms including but not limited to ANC 425, TUNE 427, AEQ 429, and ALGO 423 may be used (e.g., by DSP 532) by headset 300 and its systems to generate the modified audio signal 534 and couple via conductive path 538 the modified audio signal 534 with AMP 445. Processing by systems in headset 300 may include analyzing signals 829 and generating a counter signal (e.g., a waveform opposite in polarity and/or magnitude) to the signal 829. For example, signal 829 may include noise and the counter signal may include anti-noise. Ambient noise (371, 372) incident on transducers 342 may not be identical in magnitude, frequency content or other audio parameters to the ambient noise incident on transducers 344; therefore, processing may include taking into account differences in those audio parameters in order to more accurately determine the ambient noise component present in the signals 520a-520n from transducers 342.

Example 850 depicts an example of transducers 342 disposed in interface (331, 332) to detect sound leakage paths L_{I} along different portions of the interface (331, 332) and also depicts transducers 344 disposed in interface (331, 332) to detect incident ambient sound A_{I}. For example, positions of one or more transducers 342 and/or 344 may be selected based on empirical data for where leakage of sound may likely occur between interface (331, 332) and ear (351, 352) and its surrounding pinna for the type of interface (331, 332) being used (e.g., over-ear, on-ear, in-ear, ear bud, eartips, ear mold, etc.). The empirical data may be collected over a statistically relevant sampling of various male and female human head and ear types to account for differences in ear/pinna structure, head sizes, shapes, etc., for example. The empirical data may also include data on positions where transducers 344 may be placed to best sense incident ambient noise A_{I}. Signals 820a-820n from transducers 344 positioned on both sides of headset 300 (e.g., the left and right sides) may be processed to improve accuracy in active noise cancellation. For example, signals 820a-820n from ambient noise 371 incident on right housing 311 may be included in the processing of the modified signal 534 for sound leakage 362 and ambient noise 372 incident on the left housing 312. As another example, signals 820a-820n from ambient noise 372 incident on left housing 312 may be included in the processing of the modified signal 534 for sound leakage 361 and ambient noise 371 incident on the right housing 311.

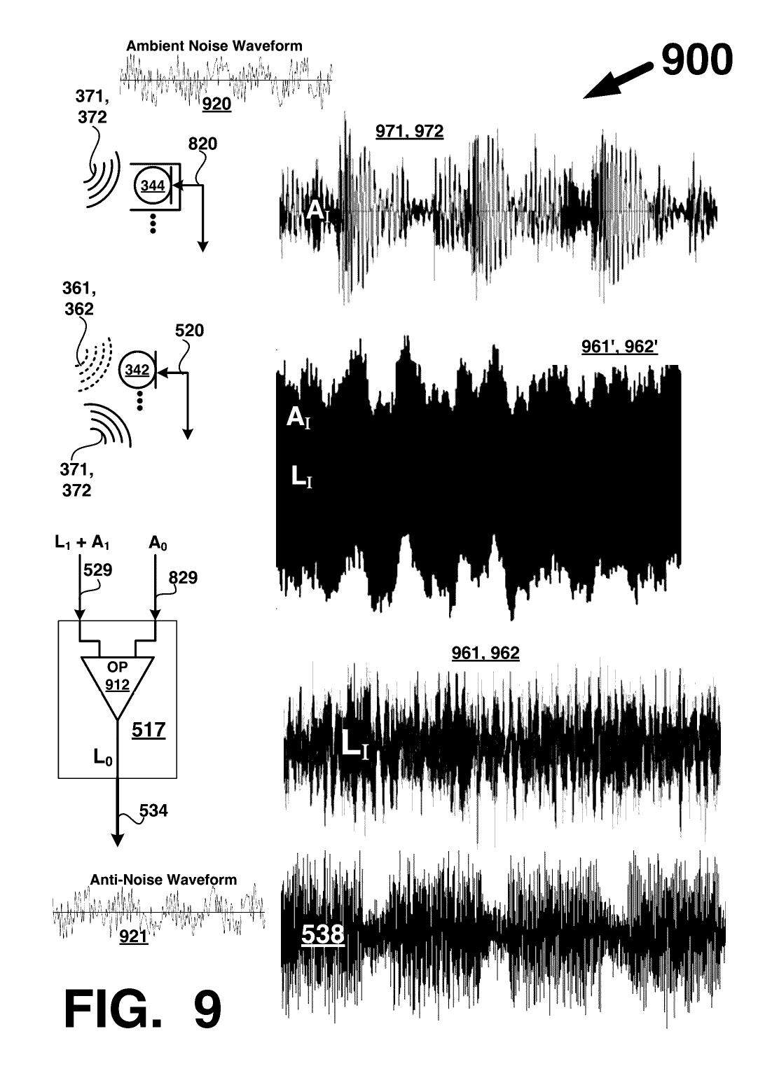

Moving now to FIG. 9 where examples 900 of transducer waveforms and generated waveforms for a headset including leakage detection and automatic noise cancellation are depicted. Transducer waveforms (971, 972) may be generated by transducers 344 in response to ambient sound (371, 372). Transducer waveforms (971, 972) may be an electrical signal 820 being generated by transducer 344 in response to incident ambient noise A_{I}, for example. Transducer 342 may generate a signal 520 that includes incident ambient noise A_{I} and sound leakage (371, 372). Therefore, transducer waveforms (961′, 962′) may include an ambient noise component A_{I} and a sound leakage component L_{I}. Although the ambient noise component A_{I} is depicted as having a larger magnitude than the sound leakage component L_{I}, actual magnitudes will be application dependent and are not limited by the example depicted for transducer waveforms (961′, 962′). Signals 520 and 820 may be processed as described above and outputs 529 and 829 from that processing may be further processed (e.g., in COMP 517) to identify the ambient noise component A_{I} in transducer waveforms (961′, 962′) and extract the sound leakage component L_{I} from transducer waveforms (961′, 962′). As one example, circuitry and/or software may perform an operation OP 812 on signal 529 (e.g., sound leakage L₁ plus ambient noise A₁) and signal 829 (e.g., ambient noise A₀) that removes (e.g., subtracts out, reduces, or cancels) the ambient noise component A_{I} in transducer waveforms (961′, 962′) and outputs a signal L₀ indicative of the sound leakage component L_{I} incident on transducer 342 minus the effect of the ambient noise component A_{I}. Signal waveforms 961 and 962 may represent a more accurate sound leakage (371, 372) waveform that may have a higher S/N ratio than would be the case if ambient noise (361, 362) was not taken into account and processed out of the waveforms 961′ and 962′, to the extent possible, using the systems of headset 300. As a result of the processing of the signals 520, 820, 529, 829, the modified audio signal 534 may be a more accurate signal (e.g., having a higher S/N ratio) to couple via conductive path 538 with AMP 445 and to drive onto loudspeaker 343 to counteract the audio effects (e.g., sound quality, frequency response, etc.) that may be caused by sound leakage.

Operation OP 912 may process an ambient noise waveform 920 associated with the ambient noise (371, 372) and a generated anti-noise waveform 921 (e.g., generated by processor(s) 410 and/or associated algorithms) that may be of opposite polarity and/or magnitude of the ambient noise waveform 920. The processing by OP 912 (e.g., using DSP 532 and/or one or more algorithms) may use the anti-noise waveform 921 to cancel out or reduce the ambient noise waveform 920 from the signals on 529 to remove ambient noise (371, 372) that may be present in the signal 520.

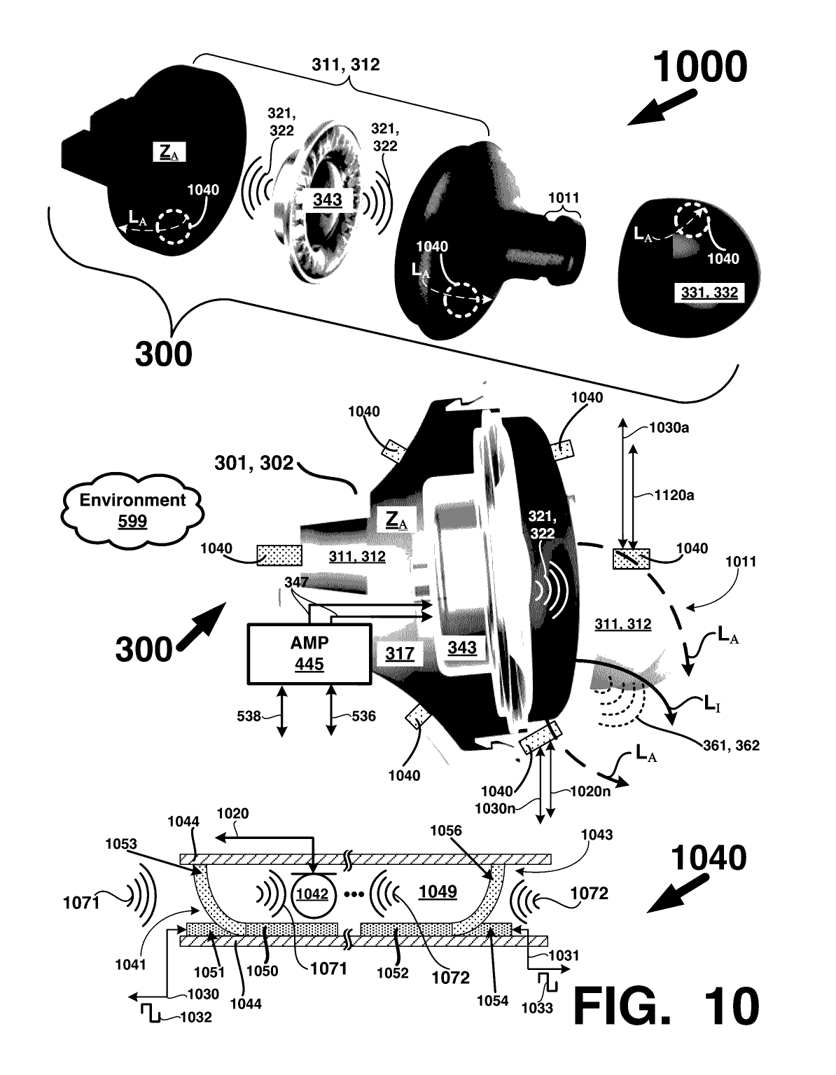

FIG. 10 depicts examples 1000 of a headset 300 with leakage detection that includes active leakage paths 1040. In example 1000, headset 300 is depicted as an in-ear type of headset; however, example 1000 is a non-limiting example presented for purposes of explanation and other types of headsets may be used, such as custom ear molds, over-ear, on-ear, etc., just to name a few. At top of FIG. 10, headset 300 is depicted in exploded view and portions (311, 312) and/or interface (331, 332) may include one or more active leakage paths 1040 (denoted in dashed line) coupled with circuitry in headset 300 (e.g., in audio system 440 and/or other systems) and operative to allow sound (321, 322) generated by loudspeaker 343 to leak out of the headset 300 through the active leakage paths 1040 as denoted by dashed arrows for active leakage L_{A}. Each active leakage path 1040 may include one or more transducers 1042 that are coupled 1020 with circuitry (e.g., in audio system 440 and/or other systems) of headset 300. Portions of interface (331, 332) (e.g., portion of an ear tip or ear bud that is not covered by the ear canal, etc.) that may not be blocked by the ear canal, pinna, or other structures of the ear may include the active leakage path(s) 1040. The active leakage paths 1040 may have identical positions or different positions on right and/or left ear cups or ear buds (301, 302) of headset 300.

In a cross-sectional view of the headset 300, active leakage paths 1040 may be positioned in one or more locations including but not limited to positions in acoustic chamber 317 that are in front of or behind loudspeaker 343. Active leakage paths 1040 may be positioned in acoustic chamber 317 to modify an acoustic impedance of chamber 317. For example, modification of the acoustic impedance of chamber 317 during real-time operation of headset 300 may include processing signals from transducers (342, 344, 1042) to alter a real-time acoustic impedance of chamber 317 to match as closely as possible an ideal acoustic impedance Z_{A}. Active leakage paths may be positioned on portions of (311, 312) that are proximate to a nipple 1011 that interface (331, 332) is coupled with. Other locations within headset 300 may be used and the non-limiting examples depicted in FIG. 10 are provided for purposes of explanation. In FIG. 10, sound (321, 322) generated by loudspeaker 343 may pass from chamber 317, through active leakage paths 1040 as denoted by dashed lines for active leakage L_{A}, and exit headset 300 into external environment 599. Moreover, sound leakage from the active leakage paths L_{A} may be in addition to the sound leakage (361, 362) from non-active leakage paths L_{I}.

A cross-sectional view of a non-limiting example of an active leakage path 1040 may include an interior chamber 1049 that may be defined by structures 1044 (e.g., a cavity, through hole, or aperture formed in a material of portions 311, 312 of headset 300). Transducer(s) 1042 may be positioned in chamber 1049 and electrically coupled 1020 (e.g., via conductive paths 1020a-1020n) with circuitry. Sound 1071 and/or 1072 may enter into chamber 1049 via openings 1041 and/or 1043 of chamber 1049. A valve, variable aperture, or other form of gating structure, denoted as 1050 may be positioned in the chamber 1049 and may be actuated from an open position or state denoted as 1051 to a closed position or state denoted as 1053. Sound 1071 may enter the chamber 1049 and impinge on transducer 1042 when valve 1050 is in the open position 1051, and sound 1071 may be blocked (e.g., or otherwise attenuated in dB's or SPL) from entering chamber 1049 and impinging on transducer 1042 when valve 1050 is in the closed position 1053. Valve 1050 may be electrically coupled 1030 (e.g., via conductive paths 1030a-1030n) with circuitry that may be operative to apply an actuation signal 1032 operative to open 1051 or close 1053 valve 1050.

Active leakage path 1040 may include more than one valve as denoted by a second valve 1052 that may be actuated between an open 1054 and a closed 1056 position by a signal 1033 applied to 1031. Sound 1072 (e.g., ambient sound from external environment 599) may enter chamber 1049 when valve 1052 is open 1054 or may be blocked from entering chamber 1049 when valve 1052 is closed 1056. In some examples, active leakage path 1040 includes a single valve (e.g., 1050 or 1052) and transducer 1042 is positioned in chamber 1049 to the left of the valve (e.g., to the left of valve 1052) or to the right of the valve (e.g., to the right of valve 1050). If positioned to the right of valve 1050, sound 1071 may be blocked from impinging on transducer 1042 when the valve 1050 is closed 1053; however, ambient noise 1072 may impinge on transducer 1042 regardless of the state of the valve 1050 (e.g., open 1051 or closed 1053). If positioned to the left of valve 1052, sound 1071 impinge on transducer 1042 regardless of the state of the valve 1052 (e.g., open 1054 or closed 1056); however, ambient noise 1072 may be blocked from impinging on transducer 1042 when the valve 1052 is closed 1056. Signals 1020 (e.g., 1020a-1020n) may be processed, muted, attenuated, ignored or otherwise handled by circuitry those signals are coupled with depending on the state of their associated valves. For example, when valve 1050 is closed 1053, signals on 1020 may be processed for ANC or the signals may be ignored. As another example, when valve 1052 is open 1054, signals generated by sounds 1071 (e.g., from loudspeaker 343) and ambient noise from environment 599 may be generated by transducer 1042 and processed accordingly by systems of headset 300 for active leakage path (ALP) and/or active noise cancellation (ANC).

In some examples a number of valves (1050, 1052) may be used to open or close one or both openings (1041, 1043) of chamber 1049. For example, both valves (1050, 1052) may be closed (1053, 1056) to block generated and ambient sound (1071, 1072) from transducer 1042. Valves (1050, 1052) may include but are not limited to a MEMS device, an artificial muscle material, a piezoelectric device, an electroactive polymer (EAP), a dielectric actuator (DEA), an actuator, a solenoid, an iris, a shutter, or other forms of actuators that may have their state (e.g., opened or closed) altered by application of a signal (e.g., a current, a voltage, an electric field).

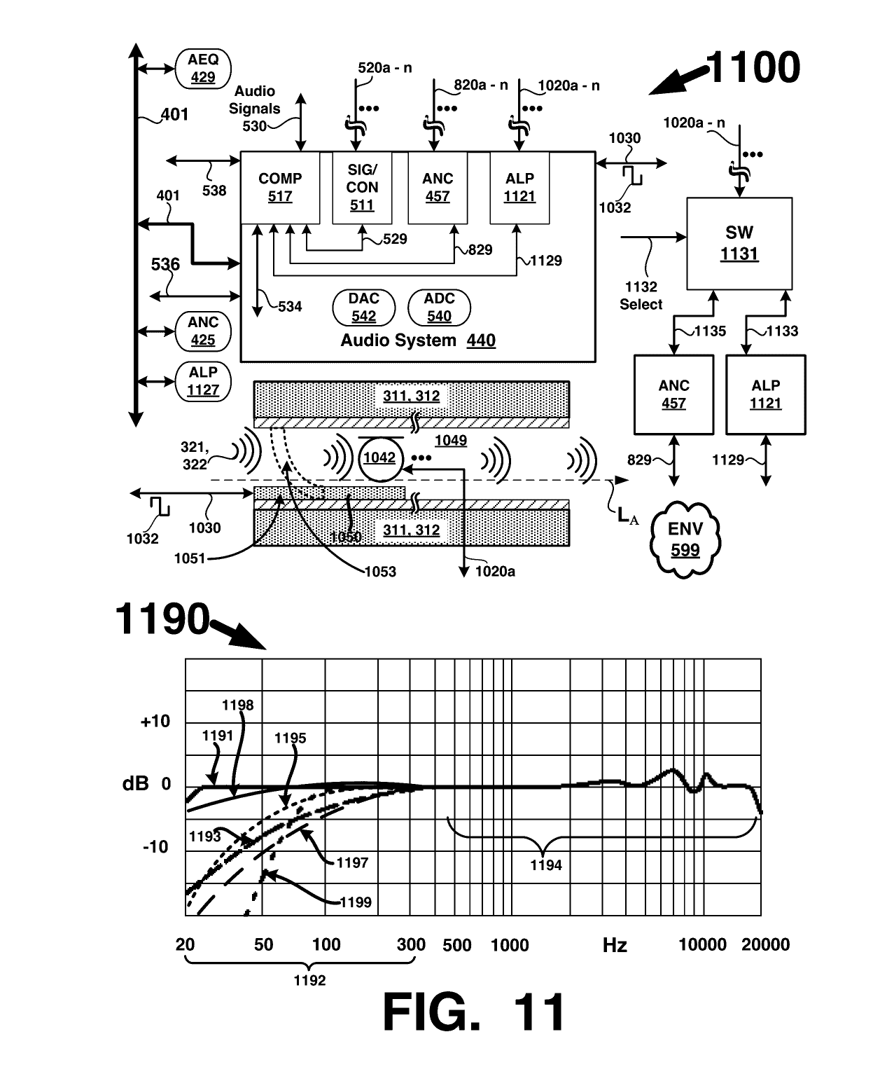

Turning now to FIG. 11 were examples of circuitry 1100 and a frequency response profile 1190 for a headset 300 with leakage detection that includes active leakage paths 1040 are depicted. Audio system 440 and/or other systems in headset 300 may be electrically coupled (1020a-1020n) with one or more of the above mentioned transducers 1042 in one or more active leakage paths 1040. Audio system 440 and/or other systems in headset 300 may be electrically coupled 1030 with one or more valves (1050, 1052) in the one or more active leakage paths 1040 and may apply signals 1032 (e.g., a voltage or current or a logic “0” or “1”) to those valves to open or close the valve as described above. Circuitry coupled (1020a-1020n) with one or more of the above mentioned transducers 1042 may include active leakage path circuitry ALP 1121 coupled 1129 with COMP 517. Signals (e.g., audio waveforms) on (1020a-1020n) may be compared with audio signals 530, with signals from transducers 342 for non-active leakage paths L_{I} as described above, and/or with signals from transducers 344 for active noise cancellation (ANC) as described above. Those signals may be processed to generate the modified audio signal via conductive path 538 and/or loudspeaker control 536 as described above. Algorithms may be used in the processing of the signals (1020a-1020n, 1029) from transducers 1042, such as an active leakage path algorithm ALP 1127, for example.

In some examples, transducers 1042 in active leakage paths 1040 may be used for ALP and/or for ANC. Accordingly, signals (e.g., 1020a-1020n) from transducers 1042 may be coupled with a switch (e.g., a MUX) SW 1131 and a select signal 1132 may be used to select which output of SW 1131 to couple the signals with. For example, if transducers 1042 are configured for ALP, then select 1132 may be activated to couple 1133 the signals (1020a-1020n) with ALP 1121. On the other hand, if transducers 1042 are configured for ANC, then select 1132 may be activated to couple 1135 the signals (1020a-1020n) with ANC 457. Signals 820a-820n from transducers 344 may also be coupled with ANC 457 along with signals (1020a-1020n).

In example 1100, active leakage path 1040 is depicted with one valve 1050 that has been activated (e.g., via signal 1032 on 1030) to an open 1051 position. Sound (321, 322) generated by loudspeaker 343 enters into chamber 1049 and impinges on transducer 1042 which generates a signal on 1020a that is indicative of the sound leaking through active path L_{A}. Sound (321, 322) may exit chamber 1049 and into external environment 599. Here, active leakage path 1040 is depicted positioned in portion (311, 312) of headset 300 (e.g., as through hole).

In FIG. 11, a frequency response profile 1190 depicts an ideal frequency response 1191 for headset 300 without leakage and frequency responses 1193, 1195 and 1197 that may be caused by leakage paths L_{I} as described above (e.g., non-active leakage paths due to coupling of interface (331, 332) with pinna, head, ear, etc. Frequency responses 1193, 1195 and 1197 may be different due to shifts in locations of leakage paths L_{I} due relative motion of the headset 300 with the users head/pinna, changes in the interface (331, 332) due to temperature, material aging, variations in pressure along the interface (331, 332) at different contact points with the pinna, etc. In that the leakage paths L_{I} may dynamically change in position and quantity over time, the resulting effects on frequency response and/or perceived audio quality may also dynamically change. For example, a low frequency response of headset 300 may be affected by leakage paths L_{I}, such that a low frequency region 1192 (e.g., from about 300 Hz to about 20 Hz) of frequency response 1190 may be more adversely affected by the leakage paths L_{I} than another region, such as higher frequency region 1194 (e.g., about 450 Hz and above). In the low frequency region 1192 the low frequency response may vary (e.g., dynamically over time) as demonstrated by different low frequency responses 1193, 1195 and 1197, for example. Active leakage paths 1040 may be selectively open and closed or remain open and processing of signals from transducers 1042 may result in an active leakage path related frequency response 1199. Frequency response 1199 may be compared with the different low frequency responses 1193, 1195 and 1197 for leakage paths L_{I} (e.g., the non-active leakage paths) to determine that the region most affected by leakage paths L_{I} is the region 1192 and appropriate signal processing (e.g., active equalization AEQ 429, ANC 425, TUNE 427, ALP 1127, etc.) may be applied to generate the modified audio signal via conductive path 538 having a frequency response 1198 that may more closely match the ideal response profile 1191.

Processing of signals 1020a-1020n by processor(s) 410 (e.g., using one or more of ANC 425, ALP 1127, TUNE 427, ALGO 423, AEQ, 429) and/or audio system 440 (e.g., by one or more of ANC 457, ALP 1121, COMP 517) may include actuating one or more valves (1050, 1052) in one or more active leakage paths 1040 to an open position or a closed position. The processing may command one or more valves (1050, 1052) to an open position to process signals from transducers (1042, 342, 344) to determine an effect of leakage on frequency response or other audio parameter, generate the modified audio signal via conductive path 538 based on the processing, and then may command one or more valves (1050, 1052) to a closed position and may process signals from transducers (1042, 342, 344) to determine if frequency response or other audio parameter has improved by the closing of the one or more valves (1050, 1052) in the active leakage paths 1040; notwithstanding the leakage that may still be ongoing from the non-active leakage paths (e.g., in the pinna interface 331, 332). The opening and closing of valves (1050, 1052) may occur at different phase or portions of the processing and valves (1050, 1052) may be opened and closed to determine their effect on the modified audio signal (e.g., a before and after comparisons of how frequency response is effected when valves are opened or closed).

In some example, amplifier control 536 may be used to vary an output impedance (e.g., from about 8Ω to about 4Ω, etc.) of amplifier 445 to increase or decrease a dampening factor (DF) of AMP 445. Increasing DF may provide greater control over low frequency excursions of a cone or motive element of loudspeaker 343 and may improve low frequency response of headset 300. Right 301 and left 302 ear cups of headset 300 may include separate circuitry and/or associated algorithms as described above in FIGS. 1 and 3-11. For example, some or all of the systems depicted in FIGS. 4, 5, 8 and 11 may be duplicated in ear cups 301 and 302. Processing in flow 100 may be duplicated in ear cups 301 and 302 (e.g., ear cups 301 and 302 include separate processors 410 and other systems). Processing (e.g., of flow 100, of algorithms for ANC, ALP, AEQ, ALGO, TUNE, etc.) may occur internal to headset 300, external to headset 300 (e.g., in client device 320 and/or resource 399 of FIG. 3), or both internal and external. Data from transducers (342, 344, 1042) may be wirelessly communicated 307 to an external device where some or all of the processing of the data may occur. Signals from loudspeaker 343 (e.g., back EMF or a motion signal from an accelerometer mechanically coupled with or in mechanical communication with loudspeaker 343 may be used as part of the processing described herein.

Transducers (342, 344, 1042) may include a microphone including but not limited to a MEMS microphone, an electret condenser (ECM) microphone, dynamic microphone, condenser microphone, piezoelectric microphone, laser microphone, carbon microphone, a loudspeaker used as a microphone, ribbon microphone, and a fiber optic microphone, just to name a few, for example. The transducers (342, 344, 1042) may include polar patterns including but not limited to omnidirectional, unidirectional, cardioid, bi-directional, pressure zone (PZM), boundary, or other patterns, for example.

Headset 300 may include one or more loudspeakers 343. Loudspeaker 343 may include but not limited to a dynamic loudspeaker, a planar magnetic loudspeaker, a piezoelectric loudspeaker, a ribbon loudspeaker, an electrostatic loudspeaker, an air motion loudspeaker (HEIL), digital loudspeaker, horn or horn loaded loudspeaker, a magnetorestrictive loudspeaker, flat panel loudspeaker, ion loudspeaker, and plasma loudspeaker, just to name a few, for example. Loudspeakers 343 in headset 300 may include one or more of coaxial loudspeaker, a full range loudspeaker, a subwoofer, a tweeter, a midrange, and a woofer, for example.

Although the foregoing examples have been described in some detail for purposes of clarity of understanding, the above-described conceptual techniques are not limited to the details provided. There are many alternative ways of implementing the above-described conceptual techniques. The disclosed examples are illustrative and not restrictive.

What is claimed is:

1. A wearable device, comprising:
a housing including an acoustic chamber having a loudspeaker disposed in the acoustic chamber, the loudspeaker electrically coupled to an amplifier;
a pinna interface coupled with the housing;
a transducer operative to generate a leakage signal from sound generated by an audio signal applied to the loudspeaker by the amplifier, the sound impinging on the transducer from a leakage path in the pinna interface; and
a processor operative to process the leakage signal and generate a modified audio signal that is electrically coupled with the amplifier, the modified audio signal operative to adjust a frequency response profile of the loudspeaker as a function of the leakage path in the pinna interface.

2. The wearable device of claim 1, wherein the processor is included in the housing.

3. The wearable device of claim 1, wherein the transducer comprises a microphone.

4. The wearable device of claim 1, wherein the housing and pinna interface are components of a headset.

5. The wearable device of claim 4, wherein the headset includes a plurality of housings and pinna interfaces.

6. The wearable device of claim 1 and further comprising:
an active noise cancellation system included in the housing and coupled with one or more active noise cancellation transducers positioned in the housing, the pinna interface or both,
wherein processing by the processor includes processing signals from the one or more active noise cancellation transducers generated by ambient noise impinging on the one or more active noise cancellation transducers, the ambient noise included in the sound impinging on the transducer from the leakage path, the processing operative to apply an active noise cancellation algorithm to cancel at least a portion of the ambient noise from the leakage signal.

7. The wearable device of claim 1 and further comprising:
one or more active leakage paths positioned in the housing, the pinna interface or both, each active leakage path including a first transducer and a first valve disposed in a chamber of the housing, the first transducer and the first valve are electrically coupled with active leakage path circuitry included in the housing, the active leakage path circuitry operative to generate a first signal that opens or closes the first valve, the first signal operative to open the first valve so that the sound generated by the loudspeaker enters the chamber and impinges on the first transducer, the first transducer generating an active leakage path signal caused by the sound impinging on it,
wherein the processor processes the active leakage path signal to generate the modified audio signal.

9. A method for a wearable device, comprising:
driving an audio signal on a loudspeaker of a headset;
sensing signals from leakage transducers included in the headset;
analyzing the signals from the leakage transducers at one or more frequencies or frequency ranges;
generating a modified audio signal based on the analyzing, the modified audio signal including a modified frequency response operative to adjust a frequency response profile of the loudspeaker as a function of the leakage path; and
driving the modified audio signal on the loudspeaker.

10. The method of claim 9 and further comprising:
applying active noise cancellation algorithms to the analyzing, the active noise cancellation algorithms operative to process active noise cancellation signals from one or more active noise cancellation transducers included in the headset.

11. The method of claim 9 and further comprising:
applying an active leakage path algorithm to the analyzing, the active leakage path algorithms operative to process active leakage path signals from one or more active leakage path transducers included in one or more active leakage paths in the headset.

12. The method of claim 11, wherein the active leakage path algorithm is operative to open or close valves positioned in the one or more active leakage paths.

13. The method of claim 9 and further comprising:
applying an active noise cancellation algorithm and an active leakage path algorithm to the analyzing,
the active noise cancellation algorithm operative to process active noise cancellation signals from one or more active noise cancellation transducers included in the headset, and
the active leakage path algorithm operative to process active leakage path signals from one or more active leakage path transducers included in one or more active leakage paths in the headset.

14. The method of claim 13, wherein the active leakage path algorithm is operative to actuate valves positioned in the one or more active leakage paths.

15. The method of claim 14, wherein during processing of the active leakage path signals, the active leakage path algorithm causes the valves to actuate to an open position during a first portion of the processing and causes the valves to actuate to a closed position during a second portion of the processing.

16. A system, comprising:
a housing including an acoustic chamber;
an audio system including a loudspeaker positioned in the acoustic chamber, an amplifier coupled with the loudspeaker, and a leakage transducer operative to generate a leakage signal coupled with circuitry in the audio system;
a pinna interface coupled with the housing, the leakage transducer positioned in the pinna interface and operative to generate the leakage signal from sound generated by an audio signal applied to the loudspeaker by the amplifier, the sound impinging on the transducer from a leakage path in the pinna interface;
a processor operative to process the leakage signal and generate a modified audio signal that is electrically coupled with the amplifier, the modified audio signal operative to adjust a frequency response profile of the loudspeaker as a function of the leakage path in the pinna interface; and
a radio frequency system including a radio operative to wirelessly communicate using one or more wireless protocols.

17. The system of claim 16 and further comprising:
a wireless client device in wireless communication with the radio frequency system, and operative to wirelessly communicate content using a wireless link between the wireless client device and the radio of the radio frequency system, the content including data that is decoded by the audio system to generate the audio signal applied to the loudspeaker.

18. The system of claim 16 and further comprising:
a wireless client device in wireless communication with the radio frequency system, and operative to wirelessly communicate content using a wireless link between the wireless client device and the radio of the radio frequency system, the wireless client device includes the processor, and data from the leakage signal is wirelessly communicated to the wireless client device using the wireless link.

19. The system of claim 16 and further comprising:
one or more active leakage paths disposed in the housing, the pinna interface or both, each active leakage path including a first transducer and a first valve disposed in a chamber housing, the first transducer and the first valve are electrically coupled with active leakage path circuitry included in the audio system, the active leakage path circuitry operative to generate a first signal that opens or closes the first valve, the first signal operative to open the first valve so that the sound generated by the loudspeaker enters the chamber and impinges on the first transducer, the first transducer generating an active leakage path signal caused by the sound impinging on it,
wherein the processor processes the active leakage path signal to generate the modified audio signal.

20. The system of claim 16 and further comprising:
an active noise cancellation system included in the audio system and coupled with one or more active noise cancellation transducers positioned in the housing, the pinna interface or both,
wherein processing by the processor includes processing signals from the one or more active noise cancellation transducers generated by ambient noise impinging on the one or more active noise cancellation transducers, the ambient noise included in the sound impinging on the leakage transducer from the leakage path, the processing operative to apply an active noise cancellation algorithm to cancel at least a portion of the ambient noise from the leakage signal.
